(19) United States
(12) Patent Application Publication
(10) Pub. No.: US 2024/0107678 A1
(43) Pub. Date: Mar. 28, 2024

(54) METHOD OF MANUFACTURING BONDED SUBSTRATE, METHOD OF MANUFACTURING CIRCUIT SUBSTRATE, AND CIRCUIT SUBSTRATE

(71) Applicants: NGK ELECTRONICS DEVICES, INC., Mine-shi (JP); NGK INSULATORS, LTD., Nagoya-shi (JP)

(72) Inventors: Kota KITAJIMA, Iruma-shi (JP); Takahiko HONDA, Gelugor (MY); Kazutaka NAKAO, Bayan Lepas (MY); Masayuki UETANI, Kasugai-shi (JP); Izumi MASUDA, Kitanagoya-shi (JP); Akihiro URANO, Kariya-shi (JP)

(21) Appl. No.: 18/524,770

(22) Filed: Nov. 30, 2023

Related U.S. Application Data
(63) Continuation of application No. PCT/JP2022/014319, filed on Mar. 25, 2022.

(30) Foreign Application Priority Data
Jun. 11, 2021 (JP) 2021-097967

(51) Int. Cl. H05K 3/00; B23K 1/19; H01L 23/373; H05K 1/02; H05K 1/03; H05K 3/24; H05K 3/38

(52) U.S. Cl. CPC H05K 3/002; B23K 1/19; H01L 23/3735; H05K 1/0209; H05K 1/0306; H05K 3/243; H05K 3/38

(57) ABSTRACT

A method of manufacturing a bonded substrate includes: preparing one or plurality of products to be bonded, each including a brazing material layer and a copper plate laminated on both main surfaces of a ceramic substrate, laminating, one or a plurality of products bonded and a pair of clamping members that clamp them while providing a mold releasing layer between each thereof, heating the one or the plurality of products while pressing the one or the plurality of products in the pair of clamping members to obtain the one or the plurality of bonded substrates in which the ceramic substrate and the copper plate are bonded with a bonding layer, and removing the mold releasing layer from the bonded substrate by dissolving a portion in contact with the mold releasing layer of the copper plate included in the bonded substrate by wet etching.

### CROSS-REFERENCE TO RELATED APPLICATION

This application is a continuation application of PCT/JP2022/014319, filed on Mar. 25, 2022, which claims the benefit of priority of Japanese Patent Application No. 2021-097967, filed on Jun. 11, 2021, the entire contents of which are incorporated herein by reference.

### TECHNICAL FIELD

The present invention relates to the manufacturing of a ceramic bonded substrate, and particularly to post-bonding processing.

### BACKGROUND ART

Silicon nitride insulating and heat dissipating circuit-boards, alumina-based insulating and heat dissipating circuit-boards, and the like are widely known as ceramic insulating and heat dissipating circuit-boards on which electronic components such as semiconductor chips are mounted. A ceramic insulating and heat dissipating circuit-board has the role of dissipating heat generated by mounted electronic components to the outside, and also serves as an electrical connection between the electronic components and the outside.

The ceramic insulating and heat dissipating circuit-board is a bonded substrate in which copper plates (sometimes referred to as copper foil, copper circuit board, copper heat dissipating board, etc.) whose main component is metallic copper, are bonded on both sides of the ceramic substrate using a brazing material containing active metals. An example of a bonding method is a pressure-heat bonding method. Typically, a semiconductor chip is bonded to (mounted on) one copper plate by silver sintering, and a metal heat dissipating plate (heat sink), for example, is soldered to the other copper plate.

Among these, a silicon nitride insulating and heat dissipating circuit-board is often used in automotive applications because of its superiority in heat dissipating property and reliability compared to an alumina-based insulating and heat dissipating circuit-board using alumina ceramic substrates. In that case, in order to improve the bonding reliability of silver sintered bonding between the semiconductor chip and the silicon nitride insulating and heat dissipating circuit-board, silver plating is applied to the surface of the copper foil that forms the silicon nitride insulating and heat dissipating circuit-board. For example, an embodiment in which silver plating is applied by electroless plating to the surface of a copper circuit board provided on one side of a silicon nitride insulating and heat dissipating circuit-board is already known (for example, see WO2020/218193).

Also, a method of bonding a copper plate and a silicon nitride ceramic substrate by pressure-heat bonding using a brazing material, which allows a plurality of bonded substrates to be obtained at the same time, is also known (for example, WO2020/105160). This method is summarized as follows, preparing a plurality of intermediary bodies (an object made by forming brazing material layers on the front and back surfaces of a silicon nitride ceramic substrate, placing copper plates on the brazing material layers), applying a coating containing a mold releasing agent (mold releasing layer) to the surface of each copper plate and then laminating the plurality of intermediary bodies, bonding in the laminated body thus obtained by heating under pressure on the whole, and finally, removing the mold releasing layers to obtain a plurality of bonded substrates.

When obtaining a plurality of bonded substrates by the method disclosed in WO2020/105160, it is required that no mold releasing layer remains on the surface of the copper plate of the obtained bonded substrates.

However, when ceramic particles are adopted as the mold releasing agent, depending on the bonding temperature, the copper particles from the softened copper plate enter the gaps between the mold releasing agent particles, forming a film of a mixture of both, resulting in the possible remaining of this film on the copper plate.

Conventionally, the film has been removed by mechanical polishing such as brush polishing (brush cleaning) or buff polishing, however, complete removal thereof has been difficult due to reasons such as embedding of the mold releasing agent particles into the copper plate, entanglement of the same due to the ductility of the copper plate, and the like.

The remaining mold releasing agent and the like cause variations in the reaction state in various treatments performed in post-processes, such as copper etching performed for patterning and surface treatment, silver plating process as disclosed in WO2020/218193 to a circuit substrate obtained by singulating the patterned bonded substrate into individual pieces, and the like. In particular, the latter becomes a factor that reduces the solder bonding strength to the silver-plating film.

### SUMMARY

The present invention relates to the manufacturing of a ceramic bonded substrate, and particularly to post-bonding processing.

According to the present invention, a method of manufacturing a bonded substrate includes steps of: preparing one or a plurality of products to be bonded, each including a brazing material layer and a copper plate laminated on both main surfaces of a ceramic substrate, laminating the one or the plurality products to be bonded and a pair of clamping members that clamp the one or the plurality products to be bonded so that the one or the plurality products to be bonded are clamped by the pair of clamping members with a mold releasing layer being provided between each thereof, heating the one or the plurality of products while pressing the one or the plurality of products in the pair of clamping members to obtain the one or the plurality of bonded substrates in which the ceramic substrate and the copper plate are bonded with a bonding layer, and removing the mold releasing layer from the bonded substrate by dissolving a portion in contact with the mold releasing layer of the copper plate included in the bonded substrate by wet etching.

According to the invention, secure removal of the mold releasing layer attached to the copper plate constituting the bonded substrate in the pressure-heat bonding method is ensured.

According to another aspect of the present invention, a circuit substrate includes a ceramic substrate, copper plates which are bonded to two main surfaces of the ceramic substrate, respectively, and silver-plating films formed on surfaces of the copper plates, in which a number of facets existing on a surface of the copper plate in an interface between the copper plate and the silver-plating film is 3000 or less per mm².

According to the invention, the number of facets that occur on the copper plate surface at the interface with the silver-plating film is reduced compared to conventional methods; therefore, the bonding strength of solder bonding to the copper plate coated with the silver-plating film is sufficiently secured.

It is therefore an object of the present invention to provide a technique for suitably removing a mold releasing layer formed on a copper plate after bonding when a bonded substrate is manufactured by a pressure-heat bonding method.

### BRIEF DESCRIPTION OF DRAWINGS

FIG. 1 is a cross-sectional view schematically illustrating a bonded substrate 100.

FIG. 2 is a flowchart illustrating a procedure for manufacturing the bonded substrate 100, including post-processes.

FIG. 3 is a diagram schematically illustrating a state in pressure-heat bonding of intermediate products 150.

FIG. 4 is a table illustrating removal states of mold releasing layer 165 when the concentration of hydrogen peroxide in the etching solution varies.

FIG. 5 is a table illustrating removal states of the mold releasing layer 165 when the etching time varies.

FIG. 6 is a table illustrating difference of states in the mold releasing layer 165 depending on the etching time when an iron chloride-based etching solution is used as the etching solution.

FIG. 7 is a SEM image of a copper plate surface after removing a silver-plating film from a circuit substrate of a comparative example.

FIG. 8 is a SEM image of a copper plate surface after removing a silver-plating film from a circuit substrate of Example.

FIG. 9 is a graph illustrating a histogram and a change in the integrated value for each section regarding the face count per mm² in a comparative example.

FIG. 10 is a graph illustrating a histogram and a change in the integrated value for each section regarding the facet count per mm² in Example.

### DESCRIPTION OF EMBODIMENT(S)

<Bonded Substrate>

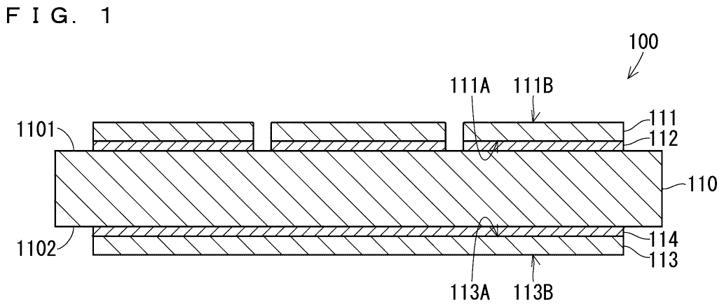

FIG. 1 is a cross-sectional view schematically illustrating a bonded substrate 100 according to a present embodiment.

The bonded substrate 100 according to the present embodiment includes a ceramic substrate 110, a copper plate 111, a bonding layer 112, a copper plate 113, and a bonding layer 114. The bonded substrate 100 may include elements other than these elements.

Although the application of the bonded substrate 100 is not particularly specified, the following description will be made assuming that the bonded substrate 100 is used as an insulating and heat dissipating substrate on which a power semiconductor element is mounted in a power semiconductor module. In such a case, it is assumed that one exposed main surface 111B of the copper plate 111 is used as a bonding surface of the power semiconductor element, whereas one exposed main surface 113B of the copper plate 113 is used as a bonding surface of a metal heat dissipating plate (heat sink). Note that, hereinafter, the main surface 111B and the main surface 113B may be collectively referred to as the copper plate surface.

Another main surface (bonding surface) 111A of the copper plate 111 is bonded to substantially the entire surface of a first main surface 1101 of the ceramic substrate 110 by the bonding layer 112. On the other hand, another main surface (bonding surface) 113A of the copper plate 113 is bonded to substantially the entire surface of a second main surface 1102 of the ceramic substrate 110 by the bonding layer 114. The first main surface 1101 and the second main surface 1102 are opposed to each other.

As the ceramic substrate 110, a wide variety of ceramic substrates that can be subjected to pressure-heat bonding, which will be described later, are applicable. Specifically, examples of the ceramic substrate 110 include a silicon nitride (Si₃N₄) substrate, an aluminum nitride (AlN) substrate, an alumina substrate, and a substrate in which zirconia particles are dispersed in alumina. Among these, silicon nitride ceramic substrates have high thermal conductivity, high insulation properties, and high mechanical strength, which is advantageous in that they are less prone to break during pressure-heat bonding. Although there are no particular restrictions on a planar shape or size of the ceramic substrate 110, from the perspective of miniaturizing a power semiconductor module, a ceramic substrate 110 having an approximately 100 mm to 250 mm in each side length, a thickness of 0.20 mm to 0.40 mm, and a rectangular shape in plan view is exemplified.

The thickness of the copper plates 111 and 113 is preferably approximately 300 μm to 2500 μm. However, it is not necessary that both values be the same.

The bonding of the ceramic substrate 110 to the copper plate 111 using the bonding layer 112 and the bonding of the ceramic substrate 110 to the copper plate 113 using the bonding layer 114 are implemented by active metal method described below. At least one metal selected from the group consisting of titanium (Ti) and zirconium (Zr) is used as the active metal. When a silicon nitride ceramic substrate is adopted as the ceramic substrate 110, the bonding layers 112 and 114 mainly contain nitride of at least one of titanium and zirconium used as the active metal. The thickness of the bonding layers 112 and 114 need only be approximately 0.1 μm or more and 5 μm or less. However, it is not necessary that both values be the same.

The copper plate 111 and the bonding layer 112 are patterned into a predetermined shape (circuit pattern) depending on the power semiconductor element to be bonded. Therefore, the first main surface 1101 of the ceramic substrate 110 is partially exposed in the bonding range of the copper plate 111. In addition to this, an aspect may also be adopted that the copper plate 113 and the bonding layer 114 are patterned. However, in the following description, for convenience, the term “bonded substrate 100” will be used to include a substrate that is not patterned.

More specifically, the bonded substrate 100 is a mother board that is to be divided into a plurality of substrates (circuit substrates) by singulation, and therefore, a number of circuit patterns having the same shape are two-dimensionally provided repeatedly on the copper plate 111 and the bonding layer 112 provided on the first main surface 1101, although detailed illustration is omitted in FIG. 1. Then, each circuit substrate is prepared for mounting a power semiconductor element.

<Manufacturing of Bonded Substrate>

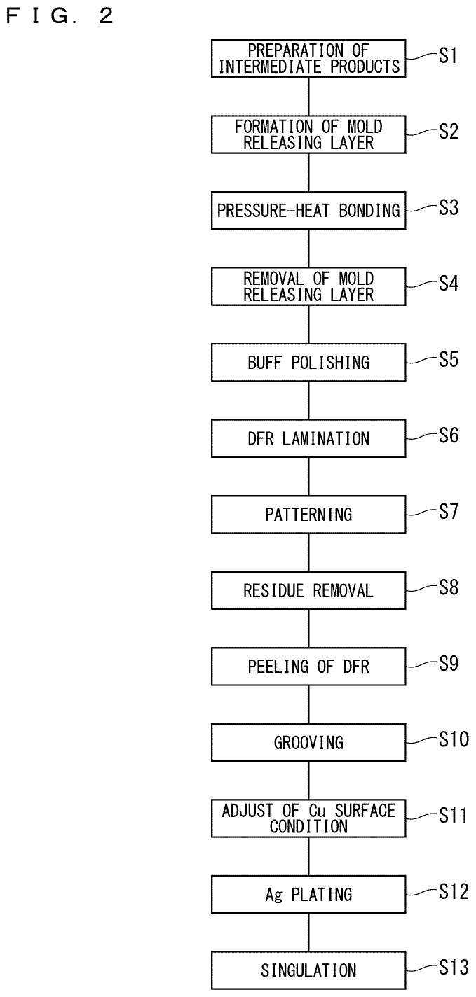

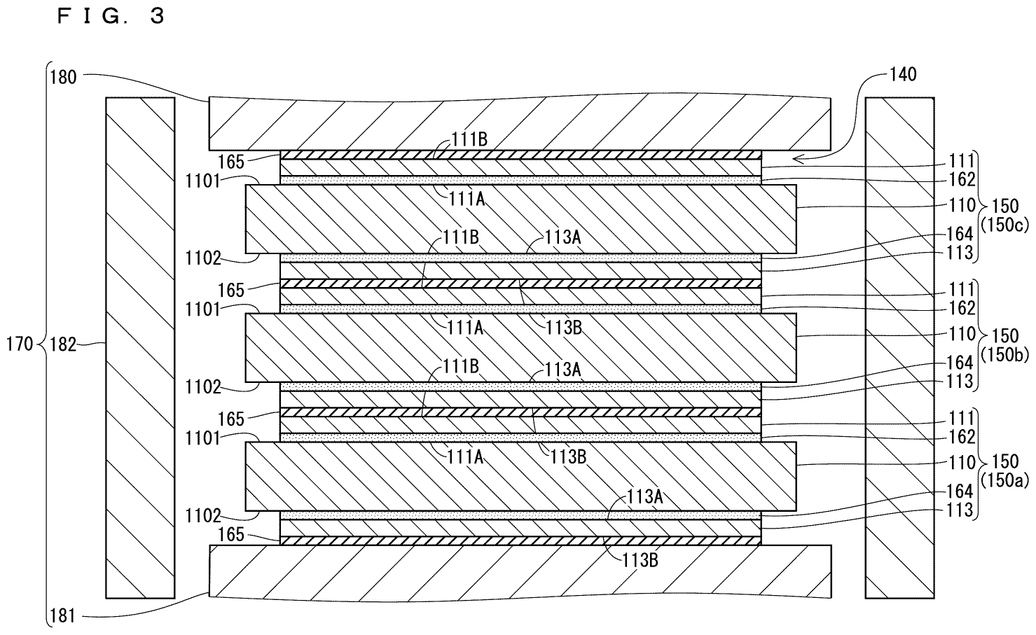

FIG. 2 is a flowchart illustrating a procedure for manufacturing the bonded substrate 100, including post-processes. In the present embodiment, bonding of the ceramic substrate 110 to the copper plates 111 and 113 to obtain the bonded substrate 100 is performed by an active metal method using an active metal brazing material. FIG. 3 is a diagram schematically illustrating the state of pressure-heat bonding of intermediate products (products to be bonded) 150, which is performed in the process of manufacturing the bonded substrate 100 by the active metal method.

(Intermediate Product)

In manufacturing the bonded substrate 100, first, a plurality of intermediate products 150 are prepared (Step S1). In the present embodiment, the bonded substrate 100 is obtained by subjecting the prepared intermediate products 150 to pressure-heat bonding and other processes.

As illustrated in FIG. 3, the intermediate product 150 has a structure in which a brazing material layer 162 and the copper plate 111 are laminated in this order on the first main surface 1101 of the ceramic substrate 110 and a brazing material layer 164 and the copper plate 113 are laminated in this order on the second main surface 1102. Note that in the state of the intermediate product 150, the copper plate 111 (or further, the copper plate 113) has not been patterned.

The brazing material layers 162 and 164 are formed by applying a paste (brazing material paste) containing an active metal brazing material and a solvent. The brazing material paste may further contain a binder, a dispersant, an antifoaming agent, and the like.

The active metal brazing material consists of powder. The active metal brazing material includes, for example, at least one metal element selected from the group consisting of silver (Ag) and copper (Cu) and at least one active metal element selected from the group consisting of titanium (Ti) and zirconium (Zr). The active metal brazing material desirably consists of a metal powder containing silver and at least one selected from the group consisting of titanium hydride (TiH₂) powder and zirconium hydride (ZrH₂) powder. In such a case, since the active metal brazing material does not contain alloy powder that is difficult to atomize at low cost, it becomes easier to atomize the active metal brazing material at low cost.

The active metal brazing material desirably consists of powder having an average particle size of 0.1 μm or more and 10 μm or less. The average particle diameter can be obtained by measuring the particle size distribution using a commercially available laser-diffraction type particle-size-distribution measuring device and calculating D50 from the measured particle size distribution. When the active metal brazing material has such a small average particle size as above, the brazing material layers 162 and 164 can be made thin.

The brazing material layers 162 and 164 are formed by applying a brazing material paste to the first main surface 1101 and the second main surface 1102 of the ceramic substrate 110. In more detail, the brazing material layers 162 and 164 are formed through evaporation of the solvent from the applied film formed as above. Then, the intermediate product 150 is formed by laminating the copper plates 111 and 113 on the brazing material layers 162 and 164, respectively. More specifically, the copper plate 111 is in contact with the brazing material layer 162 on the main surface 111A, and the copper plate 113 is in contact with the brazing material layer 164 on the main surface 113A.

(Mold Releasing Layer)

Next, the mold releasing layers 165 are formed on the main surfaces 111B of the copper plates 111 provided on all the prepared intermediate products 150, or on the main surfaces 113B of the copper plates 113 provided on all the prepared intermediate products 150 (Step S2).

However, for the intermediate product 150 located at the top and the intermediate product 150 located at the bottom in a laminate body 140, which will be described later, the mold releasing layers 165 are formed on both the main surface 111B and the main surface 113B. Alternatively, the mold releasing layer 165 may be formed on each of the main surfaces 111B and 113B of all intermediate products 150.

The mold releasing layer 165 is formed by spray coating a coating liquid containing a mold releasing agent and a solvent onto one or both of the main surface 111B and the main surface 113B, which are the formation target surfaces. More specifically, the mold releasing layer 165 is formed through evaporation of the solvent from the applied film formed by above spray coating. The coating liquid may further contain a binder, a dispersant, an antifoaming agent, and the like. The solvent includes isopropyl alcohol and the like.

Desirably, the coating liquid is electrostatically applied to the formation target surface. This prevents the coating liquid from flowing around in areas other than the formation target surface, thereby reducing loss of the coating liquid.

The mold releasing layer 165 may be formed by a method different from the method described above. For example, the mold releasing layer 165 may be provided by screen printing a paste containing a releasing agent on the formation target surface.

Although the thickness of the mold releasing layer 165 is arbitrary, it is preferably 5 μm or more and 30 μm or less. When the thickness of the mold releasing layer 165 is thinner than 5 μm, there arises a tendency that coting on the formation target surface by the mold releasing layer 165 becomes insufficient, and the copper plate 111 or the copper plate 113 is prone to be exposed. In the case that pressure-heat bonding is performed on the intermediate products 150 whose formation target surfaces are insufficiently coated with the mold releasing layers 165 as described, it may become difficult to separate the intermediate products 150 from each other, and to separate the intermediate product 150 from an upper punch 180 and a lower punch 181, which are a pair of clamping members that clamps the intermediate products 150. On the other hand, when the thickness of the mold releasing layer 165 is thicker than 30 μm, it tends to be observed that the time required to remove the mold releasing layers 165 from the intermediate products 150 after pressure-heat bonding takes longer.

The mold releasing agent consists of powder. The mold releasing agent preferably contains at least one selected from the group consisting of boron nitride (BN) powder, graphite powder, molybdenum disulfide (MoS₂) powder, and molybdenum dioxide (MoO₂) powder, and particularly preferably, consists of boron nitride powder with high heat resistance. The mold releasing agent may contain alumina.

The mold releasing agent desirably has an average particle diameter of 0.1 μm or more and 10 μm or less. The average particle diameter can be obtained by measuring the particle size distribution using a commercially available laser diffraction type particle size distribution measuring device and calculating D50 from the measured particle size distribution. When the average particle size is larger than this range, it is unfavorable because during the pressure-heat bonding of the copper plates 111 and 113 to the ceramic substrate 110, the shape of the mold releasing agent powder is transferred to the copper plate surfaces (main surface 111B and main surface 113B) in contact with the mold releasing layers 165, resulting in a deterioration of the copper plate surface roughness.

(Pressure-Heat Bonding)

A plurality of intermediate products 150 on each of which a mold releasing layer 165 is formed are laminated and arranged at a predetermined position in a pressure heat bonding device 170, and pressure-heat bonding is performed on the resulting laminate body 140 (Step S3). FIG. 3 illustrates a state in pressure-heat bonding of the laminate body 140 in which three intermediate products 150 (150a to 150c) are laminated.

As illustrated in FIG. 3, during pressure-heat bonding, the laminate body 140 is placed between the upper punch 180 and the lower punch 181 of the pressure-heat bonding device 170. Then, the laminate body 140 is clamped between the upper punch 180 and the lower punch 181 from above and below, thereby each intermediate product 150 being applied pressure. Further, in concurrent with such pressurization, the laminate body 140 is heated by a heater 182 also provided in the pressure-heat bonding device 170.

Preferably, the upper punch 180 and the lower punch 181 apply pressure in the laminating direction of the laminate body 140 during pressure-heat bonding according to a surface pressure profile in which the maximum surface pressure is set to 5 MPa or more and 25 MPa or less. Further, heating of the intermediate products 150 by the heater 182 is performed according to a temperature profile in which the maximum temperature is set to 800° C. or more and 1000° C. or less. Preferably, it is performed according to a temperature profile in which the maximum temperature is set to 800° C. or more and 900° C. or less.

The pressure-heat bonding is performed in the above manner, thereby obtaining the bonded substrate 100. In the present embodiment, a plurality of intermediate products 150 constituting the laminate body 140 are pressurized and heated at once, so a plurality of bonded substrates 100 can be obtained at the same time.

For example, in the case that the ceramic substrate 110 is made of silicon nitride ceramics, the active metal (e.g., titanium) present in the brazing material layers 162 and 164 reacts with the nitrogen of the ceramic substrate 110 in each intermediate product 150 constituting the laminate body 140, whereas silver, also present in the brazing material layers 162 and 164, diffuses into the copper plates 111 and 113. At this timing, it is also likely that other metal components contained in the active metal paste may diffuse into the copper plates 111 and 113, and silicon contained in the ceramic substrate 110 may diffuse into the brazing material layers 162 and 164.

As a result, the brazing material layers 162 and 164 are respectively changed into the bonding layers 112 and 114 mainly composed of active metal nitride, and the copper plates 111 and 113 are bonded to the ceramic substrate 110 with the bonding layers 112 and 114, respectively. As a result, the bonded substrate 100 is obtained.

Similarly, when using an oxide substrate such as an alumina substrate or a substrate in which zirconia particles are dispersed in alumina as the ceramic substrate 110, as a result of pressure-heat bonding, the brazing material layers 162 and 164 change into the bonding layers 112 and 114, thereby obtaining the bonded substrate 100.

(Removal of Mold Releasing Layer)

However, at the stage where the pressure-heat bonding is completed, the plurality of bonded substrates 100, the upper punch 180, and the lower punch 181 are in a laminated state with the mold releasing layers 165 in between. They can be separated by being peeled off from each other at the mold releasing layers 165, but the mold releasing layers 165 remain on the copper plate surfaces of respective separated bonded substrates 100. The remaining parts of the mold releasing layers 165 cause problems during patterning, plating, and the like, in post-processes. Therefore, a process is performed to remove the mold releasing layer 165 remaining on the bonded substrate 100 after separation (Step S4).

In the present embodiment, the mold releasing layer 165 is removed by wet etching. However, such wet etching does not directly dissolve and remove the remaining mold releasing layers 165 per se, but targets the portions of the copper plate surfaces, that is, the main surfaces 111B and 113B, which are in contact with the releasing layers 165. By etching the copper in the areas where the mold releasing layer 165 remains, the mold releasing layer 165 can be more securely removed.

It is preferable that the etching solution is able to etch copper and has permeability suitable for realizing to permeate the mold releasing layer 165 covering the copper plate surface and to reach the copper plate surface. In this regard, permeability can be evaluated by the surface tension of the etching solution. It can be said that the lower the surface tension, the greater the permeability.

Specifically, as the etching solution for removing the mold releasing layer 165, an etching solution having a surface tension of 70 mN/m or less is suitable. An example of such an etching solution is an aqueous solution containing 1.5% to 30% hydrogen peroxide (H₂O₂) and 1% to 20% sulfuric acid (H₂SO₄) (sulfuric acid-hydrogen peroxide based etching solution). An example of such an etching solution contains hydrogen peroxide (H₂O₂) and sulfuric acid (H₂SO₄) dissolved in water, where the mass ratio of hydrogen peroxide to the mass of the aqueous solution is 1.5% to 30%, and the mass ratio of sulfuric acid to the same is 1% to 20%. The surface tension of such a sulfuric acid-hydrogen peroxide etching solution is approximately 60 mN/m. Note that copper chloride-based or iron chloride-based etching solutions or DI water, which have a surface tension exceeding 70 mN/m and high viscosity, are not suitable for removing the mold releasing layer 165.

As for the etching time, setting of 45 seconds or more allows to remove the mold releasing layer 165 more or less suitably. In terms of the upper limit, there is no particular limitation from the point of view of complete removal of the mold releasing layer 165, however excessive etching will result in excessive thinning of the copper plates 111 and 113, so, in practice, it should be sufficient within 1000 seconds. Further, the temperature of the etching solution may be approximately 20° C. to 60° C.

After the wet etching process is completed, the exposed copper plate is then buff-polished (Step S5). Buff-polishing is performed in order to adjust the condition of the copper plate surface and roughen the copper plate surface to improve the adhesion of the dry film resist (DFR) during the next DFR lamination process to be performed.

Preferably, buff-polishing is performed in two stages: mechanical buffing and chemical buffing. The former is mainly performed for the purpose of adjusting the condition of the copper plate surface, and the latter is mainly performed for the purpose of roughening the copper plate surface. An aqueous hydrogen peroxide solution is used for the chemical buff, for example.

Noted that, in the conventional technique as disclosed in WO2020/105160, the adopted procedure is as follows: without performing wet etching for removing the mold releasing layer as described above, after pressure-heat bonding, each bonded substrate that has been separated from the other is brush-polished (brush cleaning) and then buffed. This was intended to completely remove the mold releasing layer at the buff-polishing stage, but in reality, the mold releasing layer is not necessarily completely removed by buff-polishing, and they are prone to remain on the copper plate surface in the form of mixtures with copper, and the like.

However, in the procedure adopted in the present embodiment, wet etching is performed on each of the bonded substrates 100 separated from the other after pressure-heat bonding, thereby to completely remove the mold releasing layer 165 at this timing, and then, buff-polishing is performed, as described above; therefore, the remaining mold releasing layer 165 will not cause problems in the post processes. Furthermore, since the mold releasing layer 165 is suitably removed prior to buff-polishing, buff-polishing can be performed specifically for the purpose of increasing the adhesion of the DFR.

By performing buff polishing, the bonded substrate 100 in a state before patterning is obtained.

(Patterning)

The bonded substrate 100 that has been buffed is usually subjected to a process for patterning the copper plate 111 (and the bonding layer 112) in a predetermined circuit pattern. As described above, the bonded substrate 100 is manufactured as a mother board that is divided into a number of substrates by singulation, so in patterning, a large number of circuit patterns having the same shape are two-dimensionally provided repeatedly.

First, a DFR lamination process (Step S6) is performed in which a dry film resist (DFR) is applied to substantially the entire main surface 111B that has been roughened by buff-polishing. Subsequently, patterning (Step S7) is performed by a known photolithography process.

Patterning is implemented as follows: Partially dissolving and removing the DFR using known exposure and development processes, to partially expose the main surface 111B of the copper plate 111 according to the circuit pattern desired to be formed. Subsequently, the exposed portion is etched (copper etching). An example of an etching solution for copper etching is an iron chloride-based etching solution.

Then, following the copper etching, the bonding layer 112 located directly below the position where copper was removed by the copper etching is removed (residue removal) (Step S8). The bonding layer 112 can be removed by etching or the like.

After patterning is completed, the DFR is peeled off (Step S9). For such peeling, for example, an aqueous NaOH solution is used. The bonded substrate 100 with the DFR peeled off corresponds to the bonded substrate 100 illustrated in FIG. 1.

Note that when the copper plate 113 is patterned, a series of processes including DFR lamination, patterning, residue removal, and DFR peeling are similarly performed on the main surface 113B.

(Grooving)

Hereinafter, the post-processes performed on the bonded substrate 100 will be described. First, grooving is performed (Step S10) for singulating the bonded substrate 100, which is a mother board on which a number of circuit patterns having the same shape are two-dimensionally provided repeatedly, into a number of individual circuit boards each having a unit circuit pattern in post-processing. Grooving is performed using a laser, for example. An example of the laser light source is an N₂ laser.

(Silver Plating)

Subsequently, a process for forming a silver-plating film is performed on the copper plate surface (main surface 111B and main surface 113B) of the bonded substrate 100 being the mother board after grooving. The silver-plating film is mainly formed for the purpose of increasing the bonding strength when bonding a power semiconductor element and a heat dissipating plate to a circuit substrate. In particular, this is done for the purpose of increasing the bonding strength when a metal heat dissipating plate is solder bonded to the main surface 113B.

First, prior to the formation of silver plating, a process to adjust the condition of the copper plate surface is performed (Step S11). Specifically, a degreasing process to remove organic residue remaining on the copper plate surface, and soft etching to slightly etch the copper plate surface are performed. For example, an ethylene glycol aqueous solution is used for the degreasing process. In soft etching, a hydrogen peroxide aqueous solution is used as an etching solution.

Then, electroless plating by immersion silver plating is performed on the copper plate surface whose surface condition has been adjusted through the above process (Step S12). As the plating bath, one containing approximately 10% aluminumcarboxylate and approximately 1.0 g/L of silver can be suitably used.

The bonded substrate 100, whose copper plate surfaces are silver-plated, is singulated into pieces at the positions of the previously formed grooves. Consequently, a number of individual circuit boards each having a unit circuit pattern are obtained (Step S13) from the bonded substrate 100, which is a mother board on which a number of circuit patterns having the same shape are two-dimensionally provided repeatedly.

<Effect of Removal of Mold Releasing Layer>

As described above, in the present embodiment, the plurality of bonded substrates 100 obtained in a laminated state by pressure-heat bonding are pealed from the other at the mold releasing layer 165, and then, by performing wet etching, the mold releasing layer 165 remaining on the copper plate surface of the bonding substrate 100 can be securely removed. Such a process has the effect of reducing variations in copper etching during patterning. It also has the effect of improving the state of the interface between the copper plate surface and the silver-plating film when a silver-plating film is formed by immersion silver plating on the patterned bonded substrate 100 in the post-processes.

Regarding the latter in more detail, in the case that wet etching is not performed as a process for removing the mold releasing layer, and only mechanical polishing processes such as brush polishing (brush cleaning) and buff polishing are performed, as in the conventional technique, the mold releasing layer is not necessarily removed sufficiently, and the mold releasing agent particles are prone to remain on the copper plate surface in the form of a mixture with copper or the like until the stage of forming a silver-plating film.

When immersion silver plating is performed with the mold releasing agent particles remaining as described above, the balance between copper dissolution rate and silver precipitation rate is disrupted, a number of facets are formed on the copper plate surface directly under the silver-plating film, a number of voids occur between the copper plate surface and the silver-plating film. Note that, in the present specification, the term “facet”, which originally indicates a plane (crystal plane), is used to indicate a “hole” depressed from the surroundings which is formed on the copper plate surface due to the formation of facets. The number of such holes is referred to as the number of facets or the facet count. The existence of a number of facets and voids is particularly a factor in reducing the bonding strength of solder bonding to the silver-plated copper plates. When the circuit substrate is used in a power semiconductor module, this becomes a factor that reduces the solder bonding strength of the heat dissipating plate to the main surface 113B.

Whereas, in the present embodiment, the mold releasing layer 165 is appropriately removed in wet etching before post-processing is performed; therefore, when forming a silver-plating film, the formation of voids between the silver plating and the copper plate surface due to the formation of facets on the copper plate surface is suitably suppressed. Thus, the bonding strength of solder bonding to the copper plate coated with the silver-plating film is sufficiently secured. When the circuit substrate is used in a power semiconductor module, the solder bonding strength of the heat dissipating plate to the main surface 113B is sufficiently secured.

Specifically, for a bonded substrate or a circuit substrate manufactured using conventional procedures in which wet etching is not performed, the facet count per mm² of the copper plate surface reaches tens of thousands, whereas for the copper plate surface of the bonded substrate or a circuit substrate manufactured by the procedure according to the present embodiment, which is manufactured by the procedure described above, the facet count per mm² reduces to 3000 or less. Consequently, the bonding strength of solder bonding is reliably secured.

Preferably, the number of facets with a diameter (facet diameter) of 2.5 μm or more is 1200 or less per mm², and the number of facets with a facet diameter of less than 2.5 μm is 1800 or less per mm². More preferably, the number of facets with a facet diameter of less than 1.5 μm is 1200 or less per mm². In this condition, the bonding strength of solder bonding is more reliably secured.

As described above, according to the present embodiment, in a case where a plurality of intermediate products, each consisting of a brazing material layer and a copper plate laminated on both main surfaces of a ceramic substrate, are laminated with mold releasing layers interposed therebetween, and pressure-heat bonding is performed on the resulting laminate body to obtain a plurality of bonded substrates at once, the mold releasing layer remaining on the bonded substrate after pressure heat bonding is securely removed by wet etching that dissolves the surfaces of the copper plates, thereby securely removing the mold releasing layer. This reduces variations in copper etching during subsequent patterning. The state of the interface between the copper plate surface and the silver-plating film is improved when a silver-plating film is formed by immersion silver plating on the copper plate surface of the bonded substrate in the post-processes.

Particularly in the latter case, the formation of voids between the copper plate and the copper plate surface due to the formation of facets on the copper plate surface is suitably suppressed; therefore, the solder bonding strength to the copper plate coated with the silver-plating film is sufficiently secured.

<Modification>

Although in the embodiment described above, the laminate body of the plurality of intermediate products was subjected to pressure-heat bonding, an aspect may also be adoptable in which only one intermediate product is the target subjected to pressure-heat bonding, and in one bonded substrate obtained thereby, the mold releasing layer attached to the copper plate may be removed by wet etching.

The processes of grooving (Step S10) and singulation (Step S13) in the above-described embodiment may be omitted. When the circuit substrate used in a power semiconductor module has large dimensions, such processes may be taken. That is, one bonded substrate 100 may be used as a whole in a power semiconductor module, as it is.

### Example

(Confirmation of Removal of Mold Releasing Layer)

An experiment was conducted to confirm the effect of removal of the mold releasing layer 165 remaining on the bonding substrate 100 by wet etching. Boron nitride (BN) powder was employed as the mold releasing agent, and as the etching solution, a sulfuric acid-hydrogen peroxide based etching solution was employed.

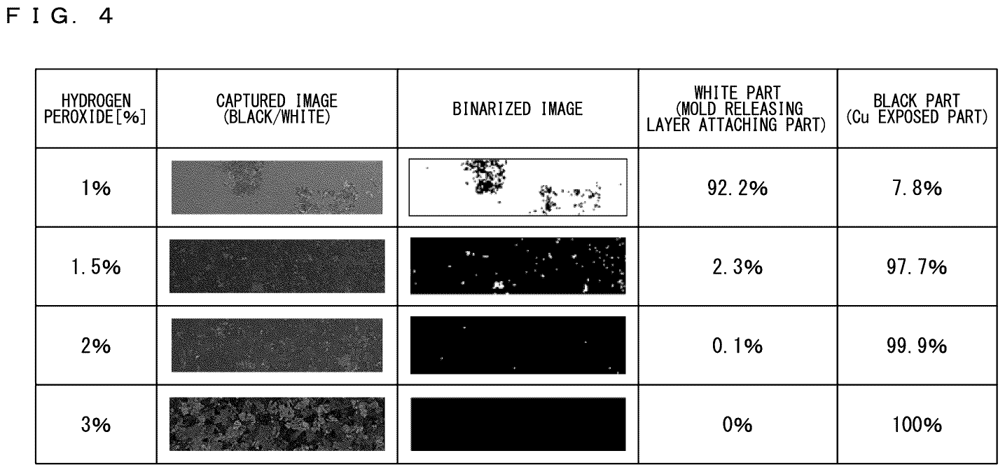

FIG. 4 is a table illustrating a removal state of the mold releasing layer 165 when the concentration of hydrogen peroxide in the etching solution was changed using captured images (partially) actually captured by a camera, binarized images of the captured images, and area ratios of white parts and black parts in the binarized image identified by image analysis.

The banalization process to identify the white parts and black parts was performed as follows: based on the captured images, forming a density histogram chart with the vertical axis representing the number of appearing pixels and the horizontal axis representing gray levels (density values) of 256 gradations from 0 to 255, and, with a gray level threshold set to 100, determining pixels with gray levels below 100 as black, pixels with gray levels 100 or higher as white. The reason the gray level threshold is set to 100 is that, when the copper plate surface was completely covered with the mold releasing layer 165 and was not exposed at all, the number of appearing pixels in the gray level range of 0 to 100 was almost 0, and the number of appearing pixels peaked in the gray level range of 100 to 255, whereas, when the mold releasing layer 165 was completely removed and the entire copper plate surface was exposed, the number of appearing pixels in the gray level range of 100 to 255 was almost 0, and the number of appearing pixels peaked in the gray level range of 0 to 100.

More specifically, concentration of the hydrogen peroxide of the sulfuric acid-hydrogen peroxide based etching solution was varied in 4 levels of 1%, 1.5%, 2%, and 3%, concentration of the sulfuric acid was set to 10%, the temperature was set to 40° C., and the etching time was set to 160 seconds.

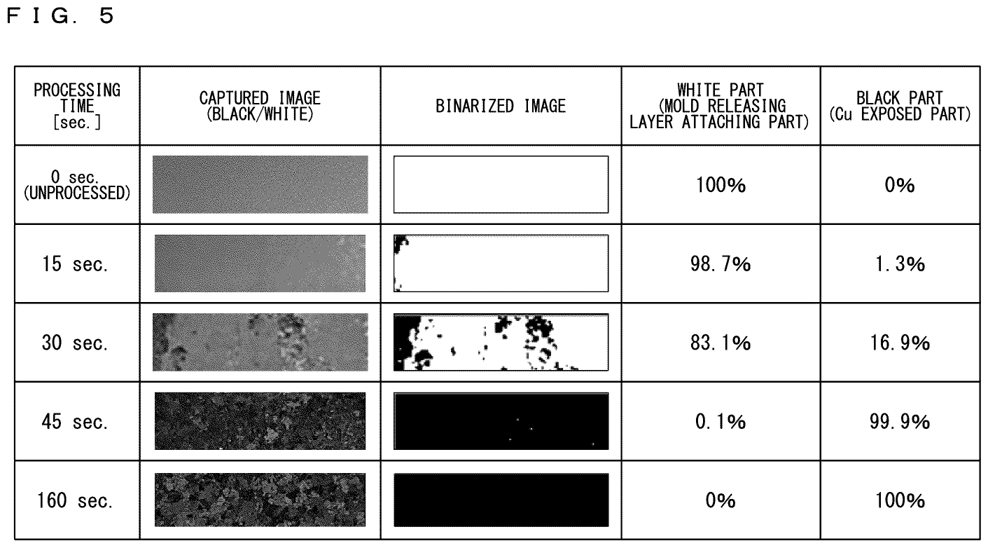

On the other hand, FIG. 5 illustrates the removal states of the mold releasing layer 165 at different etching times, using the captured images, binarized images, and area ratios of white parts and black parts in the binarized image similar to FIG. 4.

More specifically, the hydrogen peroxide concentration of the etching solution was set to 3%, the sulfuric acid concentration was set to 10%, the temperature was set to 40° C., and the etching times was varied in 5 levels of 0 seconds (that is, unprocessed), 15 seconds, 30 seconds, 45 seconds, and 160 seconds.

From FIGS. 4 and 5, it is confirmed that the mold releasing layer is almost completely removed when hydrogen peroxide is 1.5% or more and the etching time is 45 seconds or more.

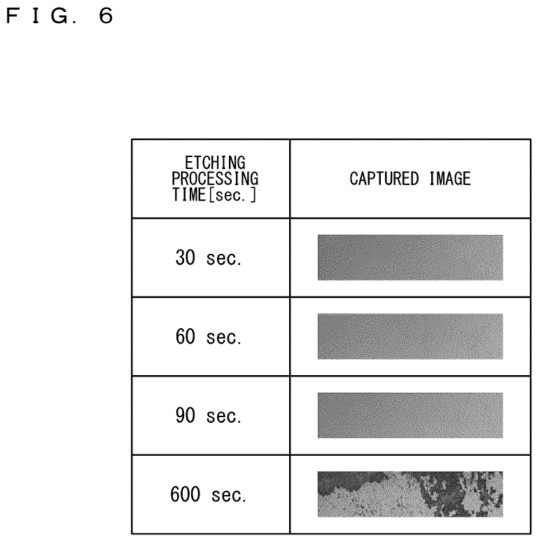

Meanwhile, FIG. 6 is a table illustrating difference of states in the mold releasing layer 165 depending on the etching time when an iron chloride-based etching solution is used as the etching solution using the same captured images similar to FIG. 4. The etching time were varied in 4 levels of 30 seconds, 60 seconds, 90 seconds, and 600 seconds.

From FIG. 6, it is confirmed that there is almost no change in the mold releasing layer 165 up to 90 seconds. Further, it is also confirmed that a large amount of the mold releasing layer 165, which is visually recognized as white, remains even at 600 seconds. The results indicate that the iron chloride-based etching solution is not suitable for removing the mold releasing layer 165.

(Surface Tension Evaluation)

Surface tension, which serves as an indicator of permeability, was measured for the sulfuric acid-hydrogen peroxide etching solution, the iron chloride-based etching solution, and DI water.

As the sulfuric acid-hydrogen peroxide based etching solution, an aqueous solution with a hydrogen peroxide concentration of 3% and a sulfuric acid concentration of 10% was measured. As the iron chloride-based etching solution, an aqueous solution with an iron chloride concentration of 40% and a hydrochloric acid concentration of 10% was measured.

CBVP-Z, the product of Kyowa Interface Science Co., Ltd., was used as a measuring device, the plate method was used as the measuring method, and the measuring temperature was 20° C.

The measurement results were as follows:
Sulfuric acid-hydrogen peroxide based: 60.6 mN/m;
Iron chloride based: 77.8 mN/m;
DI water: 73.1 mN/m.

Considering the above results along with the results illustrated in FIGS. 4 to 6, it is suggested that the sulfuric acid-hydrogen peroxide based etching solution, which has low surface tension and excellent permeability, is suitable for removing the mold releasing layer 165.

(Facet Count Evaluation)

Next, in order to confirm the usefulness of applying wet etching to remove the mold releasing layer 165, the number of facets existing on the circuit substrate on which the silver-plating film was formed was evaluated. As Example, a circuit substrate was prepared which was manufactured by removing the mold releasing layer 165 by wet etching using a sulfuric acid-hydrogen peroxide based etching solution with a hydrogen peroxide concentration of 3% and a sulfuric acid concentration of 10%, and then following the procedure illustrated in FIG. 2. As a comparative example, a circuit substrate (5 cm×5 cm) was prepared which was manufactured by brush cleaning instead of wet etching and following the procedure illustrated in FIG. 2.

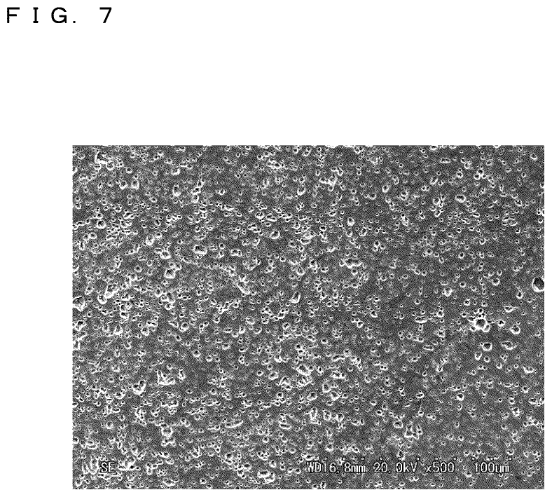

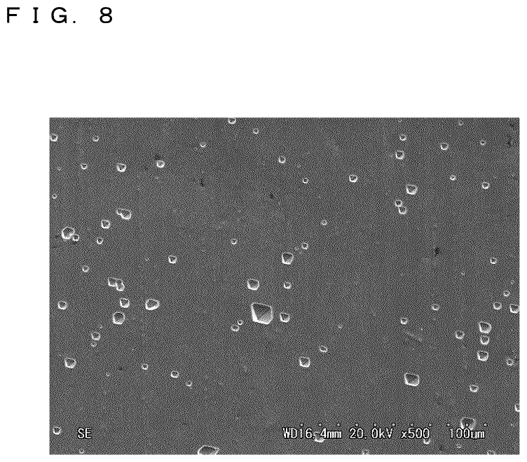

When counting the number of facets, first, the silver-plating film formed on the circuit substrate is removed using an aqueous solution containing potassium permanganate and sodium hydroxide, and then, an SEM (HITACHI S-3000N) was used to capture images of a 180 μm×240 μm area at three arbitrary locations on the copper plate surface. FIG. 7 is a captured image of the circuit substrate of the comparative example, and FIG. 8 is a captured image of the circuit substrate of Example. Subsequently, the obtained captured image (magnification: 500×) was printed out, and all facets in the printed captured image were counted for each section categorized by diameter (facet diameter). Specifically, the maximum diameter of the facet in a certain direction of the captured image (for example, the longitudinal direction of the rectangular captured image) was defined as the diameter of the facet, and the diameter of each facet was measured using a ruler. Also, the facet diameter was expressed in μm, rounded to the second decimal place, and counted for each of the following 11 sections. Note the similar measurement may be performed by image analysis.
Section 1: 0.5 μm or more, 1.4 μm or less (less than 1.5 μm);
Section 2: 1.5 μm or more, 2.4 μm or less (less than 2.5 μm);
Section 3: 2.5 μm or more, 3.4 μm or less (less than 3.5 μm);
Section 4: 3.5 μm or more, 4.4 μm or less (less than 4.5 μm);
Section 5: 4.5 μm or more, 5.4 μm or less (less than 5.5 μm);
Section 6: 5.5 μm or more, 6.4 μm or less (less than 6.5 μm);
Section 7: 6.5 μm or more, 7.4 μm or less (less than 7.5 μm);
Section 8: 7.5 μm or more, 8.4 μm or less (less than 8.5 μm);
Section 9: 8.5 μm or more, 9.4 μm or less (less than 9.5 μm);
Section 10: 9.5 μm or more, 10.4 μm or less (less than 10.5 μm);
Section 11: 10.5 μm or more.

Note that facets with a diameter of less than 0.5 μm were excluded because of their challenging identification.

In table 1, for the cooperative example and Example, facet count values for each section in each of the three counting target ranges, the total facet count of the three counting ranges for each section (“Total” column in Table 1), the facet count per mm², which is calculated by dividing the total facet count by the total area of the counting range (180 μm×240 μm×3=0.1296 mm²) (“Per mm²” column in Table 1), and the integrated values obtained by integrating the facet count per mm² and each section start from the smaller facet diameter, are listed.

TABLE 1

| | Facet | Comparative example | | | | | | Example | | | | | |
|---|---|---|---|---|---|---|---|---|---|---|---|---|---|
| | diameter | | | | | Per | Integrated | | | | | Per | Integrated |
| Section | [μm] | 1 | 2 | 3 | Total | mm² | value | 1 | 2 | 3 | Total | mm² | value |
| 1 | 0.5~1.4 | 798 | 830 | 1236 | 2864 | 22099 | 22099 | 7 | 120 | 13 | 140 | 1080 | 1080 |
| 2 | 1.5~2.4 | 106 | 125 | 149 | 380 | 2932 | 25031 | 18 | 27 | 18 | 63 | 486 | 1566 |
| 3 | 2.5~3.4 | 32 | 41 | 16 | 89 | 687 | 25718 | 17 | 17 | 21 | 55 | 424 | 1990 |
| 4 | 3.5~4.4 | 18 | 15 | 9 | 42 | 324 | 26042 | 14 | 17 | 12 | 43 | 332 | 2322 |
| 5 | 4.5~5.4 | 10 | 17 | 4 | 31 | 239 | 26281 | 6 | 9 | 8 | 23 | 177 | 2499 |
| 6 | 5.5~6.4 | 9 | 16 | 3 | 28 | 216 | 26497 | 3 | 4 | 9 | 16 | 123 | 2622 |
| 7 | 6.5~7.4 | 6 | 7 | 2 | 15 | 116 | 26613 | 3 | 3 | 1 | 7 | 54 | 2676 |
| 8 | 7.5~8.4 | 3 | 6 | 0 | 9 | 69 | 26682 | 2 | 1 | 0 | 3 | 23 | 2699 |
| 9 | 8.5~9.4 | 1 | 2 | 0 | 3 | 23 | 26705 | 0 | 1 | 0 | 1 | 8 | 2707 |
| 10 | 9.5~10.4 | 1 | 1 | 1 | 3 | 23 | 26728 | 0 | 0 | 0 | 0 | 0 | 2707 |
| 11 | 10.5~ | 0 | 1 | 0 | 1 | 8 | 26736 | 0 | 0 | 1 0 | 0 | 0 | 2707 |

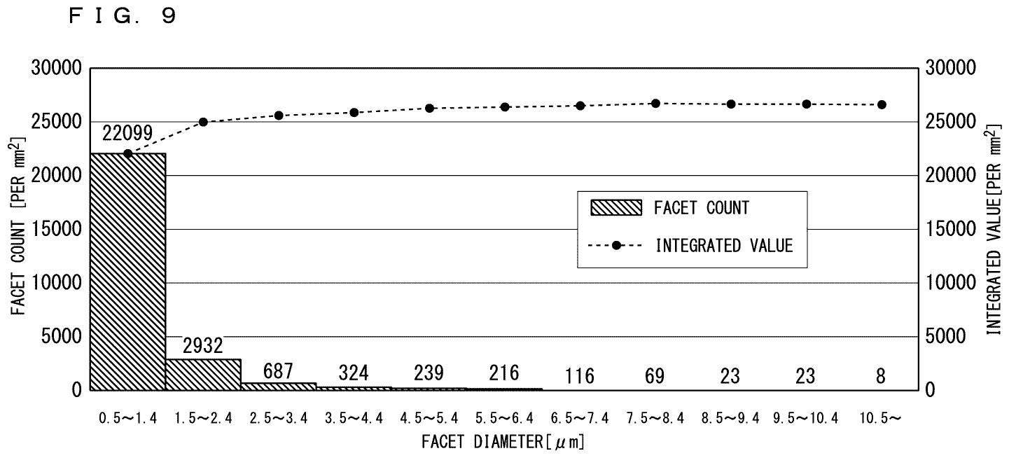

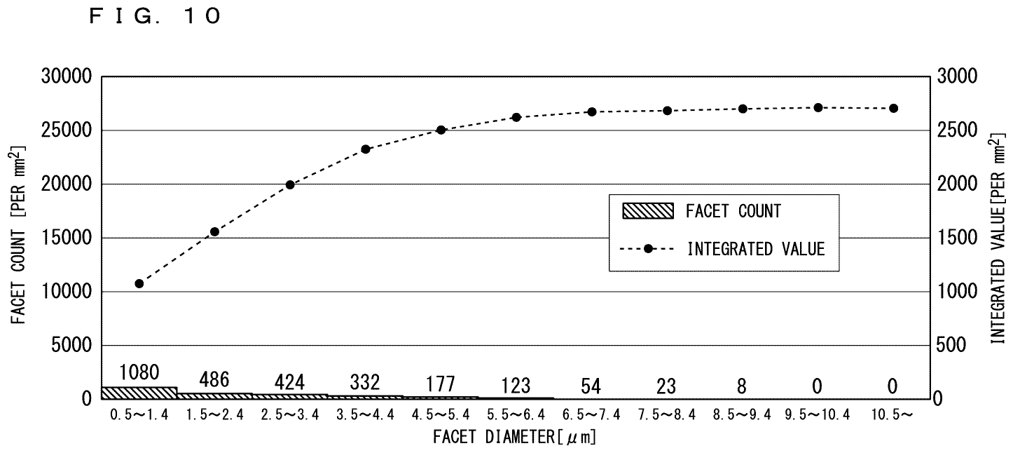

FIG. 9 is a graph illustrating a histogram and a change in the integrated value for each section regarding the facet count per mm² in the comparative example. On the other hand, FIG. 10 is a graph illustrating a histogram and a change in the integrated value for each section regarding the facet count per mm² in Example.

As can be seen from Table 1 and FIGS. 9 and 10, in the case of the comparative example, the total facet count is 26736 per mm², whereas in the case of Example, the total facet count remained at 2707, which is less than 3000 per mm². That is, in Example, the facet count was reduced to approximately 1/10 of that in the comparative example. This shows that performing wet etching to remove the mold releasing layer is effective for reducing facets.

More specifically, in the case of the comparative example, the number of facets with a facet diameter of 2.5 μm or more is 26736−25031=1705 per mm², whereas in the case of Example, the number of facets with a facet diameter of 2.5 μm or more is 2707−1566=1141 per mm², which was less than 1200, however, it can be said that the difference from the comparative example is rather small.

However, in the case of the comparative example, the number of facets with a facet diameter of less than 1.5 μm is extremely large at 22099 per mm², also the number of facets with a facet diameter of less than 2.5 μm reaches 25031 per mm². On the other hand, in the case of Example, the number of facets with a facet diameter of less than 1.5 μm is only at 1080 per mm², and also the number of facets with a facet diameter of less than 2.5 μm is also at 1566 per mm².

This difference suggests that in the case of the example, the formation of facets with a small diameter is more effectively suppressed, and this is effective in securing solder bonding strength to a copper plate coated with a silver-plating film.

1. A method of manufacturing a bonded substrate comprising steps of:
(a) preparing one or a plurality of products to be bonded, each including a brazing material layer and a copper plate laminated on both main surfaces of a ceramic substrate;
(b) laminating the one or the plurality products to be bonded and a pair of clamping members that clamp the one or the plurality products to be bonded so that the one or the plurality products to be bonded are clamped by the pair of clamping members with a mold releasing layer being provided between each thereof;
(c) heating the one or the plurality of products while pressing the one or the plurality of products in the pair of clamping members, to obtain the one or the plurality of bonded substrates in which the ceramic substrate and the copper plate are bonded with a bonding layer; and
(d) removing the mold releasing layer from the bonded substrate by dissolving a portion in contact with the mold releasing layer of the copper plate included in the bonded substrate by wet etching.

2. The method of manufacturing the bonded substrate according to claim 1, wherein,
in the step (c), the one or the plurality of products are pressed according to a surface pressure profile in which the maximum surface pressure is set to 5 MPa or more and 25 MPa or less.

3. The method of manufacturing the bonded substrate according to claim 1, wherein,
in the step (d), an etching solution having a surface tension of 70 mN/m or less is used.

4. The method of manufacturing the bonded substrate according to claim 3, wherein
the etching solution is a sulfuric acid-hydrogen peroxide based etching solution containing 1.5% to 30% hydrogen peroxide and 1% to 20% sulfuric acid.

5. The method of manufacturing the bonded substrate according to claim 3, wherein,
in the step (d), an etching time is set to 45 seconds or more.

6. The method of manufacturing the bonded substrate according to claim 1, further comprising a step of
(e) buff-polishing the copper plate of the bonded substrate after the step (d).

7. A method of manufacturing a circuit substrate comprising steps of:
manufacturing a bonded substrate with steps of:
(a) preparing one or a plurality of products to be bonded, each including a brazing material layer and a copper plate laminated on both main surfaces of a ceramic substrate;
(b) laminating the one or the plurality products to be bonded and a pair of clamping members that clamp the one or the plurality products to be bonded so that the one or the plurality products to be bonded are clamped by the pair of clamping members with a mold releasing layer being provided between each thereof;
(c) heating the one or the plurality of products while pressing the one or the plurality of products in the pair of clamping members, to obtain the one or the plurality of bonded substrates in which the ceramic substrate and the copper plate are bonded with a bonding layer; and
(d) removing the mold releasing layer from the bonded substrate by dissolving a portion in contact with the mold releasing layer of the copper plate included in the bonded substrate by wet etching,
forming a predetermined circuit pattern on the bonded substrate; and
performing immersion silver plating on a surface of the copper plate of the bonded substrate after the patterning.

8. A circuit substrate comprising:
a ceramic substrate;
copper plates which are bonded to two main surfaces of the ceramic substrate, respectively; and
silver-plating films formed on surfaces of the copper plates, wherein
a number of facets existing on a surface of the copper plate in an interface between the copper plate and the silver-plating film is 3000 or less per mm².

9. The circuit substrate according to claim 8, wherein
the number of facets with a diameter of 2.5 μm or more is 1200 or less per mm², and the number of facets with a diameter of less than 2.5 μm is 1800 or less per mm².

10. The circuit substrate according to claim 9, wherein
the number of facets with a facet diameter of less than 1.5 μm is 1200 or less per mm².

11. The method of manufacturing the bonded substrate according to claim 2, further comprising a step of
(e) buff-polishing the copper plate of the bonded substrate after the step (d).

12. The method of manufacturing the circuit substrate according to claim 7, wherein,
in the step (c), the one or the plurality of products are pressed according to a surface pressure profile in which the maximum surface pressure is set to 5 MPa or more and 25 MPa or less.

13. The method of manufacturing the circuit substrate according to claim 7, wherein,
in the step (d), an etching solution having a surface tension of 70 mN/m or less is used.

14. The method of manufacturing the circuit substrate according to claim 13, wherein
the etching solution is a sulfuric acid-hydrogen peroxide based etching solution containing 1.5% to 30% hydrogen peroxide and 1% to 20% sulfuric acid.

15. The method of manufacturing the circuit substrate according to claim 13, wherein,
in the step (d), an etching time is set to 45 seconds or more.

16. The method of manufacturing the circuit substrate according to claim 7, further comprising a step of
(e) buff-polishing the copper plate of the bonded substrate after the step (d).

17. The method of manufacturing the circuit substrate according to claim 12, further comprising a step of
(e) buff-polishing the copper plate of the bonded substrate after the step (d).

18. The method of manufacturing the circuit substrate according to claim 12, wherein,
in the step (d), an etching solution having a surface tension of 70 mN/m or less is used.

19. The method of manufacturing the circuit substrate according to claim 18, wherein
the etching solution is a sulfuric acid-hydrogen peroxide based etching solution containing 1.5% to 30% hydrogen peroxide and 1% to 20% sulfuric acid.

20. The method of manufacturing the circuit substrate according to claim 18, wherein,
in the step (d), an etching time is set to 45 seconds or more.
